(19) United States
(12) Patent Application Publication
(10) Pub. No.: US 2025/0393320 A1
(43) Pub. Date: Dec. 25, 2025

(54) IMAGE SENSOR AND METHOD OF MANUFACTURING THE SAME

(71) Applicant: VisEra Technologies Company Limited, Hsin-Chu City (TW)

(72) Inventors: Hsuan-Chun CHANG, Hsin-Chu City (TW); Wei-Hsiang LIN, Hsin-Chu City (TW); Wen-Yu SHIH, Hsin-Chu City (TW)

(21) Appl. No.: 18/750,068

(22) Filed: Jun. 21, 2024

(51) Int. Cl. H01L 27/146

(52) U.S. Cl. CPC H10F 39/805; H10F 39/024; H10F 39/182

(57) ABSTRACT

A method of manufacturing an image sensor is provided. The method includes providing a substrate and forming a bottom electrode and a top electrode on a top surface of the substrate. The bottom electrode is spaced apart from the top electrode. The method further includes forming a photosensitive layer over the substrate to cover the bottom electrode and the top electrode. The method further includes patterning the photosensitive layer to expose the top electrode. The method further includes forming a multi-layer conductive layer over the substrate. The multi-layer conductive layer electrically connects the top electrode and the photosensitive layer. The multi-layer conductive layer includes a top optical spacer layer in direct contact with a top surface of the photosensitive layer.

### BACKGROUND OF THE INVENTION

### Field of the Invention

The present disclosure relates to an image sensor, and in particular to an image sensor combining a photosensitive layer and optical spacer layers.

### Description of the Related Art

Image sensors, such as complementary metal oxide semiconductor (CMOS) image sensors (also known as CIS), are widely used in various image-capturing apparatuses such as digital still-image cameras, digital video cameras, and the like. The light-sensing portion of the image sensor may detect ambient color changes, and signal electric charges may be generated depending on the amount of light received in the light-sensing portion. In addition, the signal electric charges generated in the light-sensing portion may be transmitted and amplified to obtain an image signal.

In addition, the photosensitive layer may be used in conjunction with image sensors (such as a CMOS image sensor). In order to increase the absorption efficiency of the photosensitive layer, the cavity of the photosensitive layer needs to be enlarged. This may enhance image quality.

However, existing photosensitive layers have not been satisfactory in all respects. The greater the thickness of the photosensitive layer, the higher the cost. In order for the finished product to maintain a low cost and a high level of performance, the industry still needs to improve the photosensitive layer to achieve their goal of maintaining the yield of image sensors.

### BRIEF SUMMARY OF THE INVENTION

An embodiment of the present disclosure provides a method of manufacturing an image sensor. The method includes providing a substrate and forming a bottom electrode and a top electrode on a top surface of the substrate. The bottom electrode is spaced apart from the top electrode. The method includes forming a photosensitive layer over the substrate to cover the bottom electrode and the top electrode. The method includes patterning the photosensitive layer to expose the top electrode. The method includes forming a multi-layer conductive layer over the substrate. The multi-layer conductive layer electrically connects the top electrode and the photosensitive layer. The multi-layer conductive layer includes a top optical spacer layer in direct contact with a top surface of the photosensitive layer.

An embodiment of the present disclosure provides an image sensor. The image sensor includes a substrate. The image sensor includes a bottom electrode and a top electrode disposed on the substrate. The bottom electrode is spaced apart from the top electrode. The image sensor includes a photosensitive layer disposed over the bottom electrode. The image sensor includes a multi-layer conductive layer disposed over the substrate. The multi-layer conductive layer electrically connects the photosensitive layer and the top electrode. The multi-layer conductive layer comprises a top optical spacer layer in direct contact with a top surface of the photosensitive layer.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a cross-sectional view of the image sensor, according to some embodiments of the present disclosure;

FIG. 2 illustrates a cross-sectional view of the image sensor forming the bottom optical spacer layer, according to some embodiments of the present disclosure;

FIG. 3 illustrates a cross-sectional view of the image sensor sequentially forming the photosensitive layer and the top optical spacer layer, according to some embodiments of the present disclosure;

FIGS. 4, 5, 6, and 7 illustrate cross-sectional views of the image sensor patterning the top optical spacer layer, the photosensitive layer, and the bottom optical spacer layer, according to some embodiments of the present disclosure;

FIG. 8 illustrates a cross-sectional view of the image sensor forming the conductive layer, according to some embodiments of the present disclosure;

FIGS. 9, 10, 11, and 12 illustrate cross-sectional views of the image sensor patterning the conductive layer, according to some embodiments of the present disclosure;

FIG. 13 illustrates a cross-sectional view of the image sensor forming the anti-reflective coating layer, according to some embodiments of the present disclosure;

FIGS. 14, 15, 16, and 17 illustrate cross-sectional views of the image sensor patterning the anti-reflective coating layer, according to some embodiments of the present disclosure;

FIG. 18 illustrates a fragmentary cross-sectional view of the image sensor, according to some embodiments of the present disclosure;

FIG. 19 illustrates a light absorption view of the image sensor, according to some embodiments of the present disclosure;

FIG. 20 illustrates a cross-sectional view of the image sensor, according to some embodiments of the present disclosure;

FIG. 21 illustrates a cross-sectional view of the image sensor forming the photosensitive layer, according to some embodiments of the present disclosure;

FIGS. 22, 23, 24, and 25 illustrate cross-sectional views of the image sensor patterning the photosensitive layer, according to some embodiments of the present disclosure;

FIG. 26 illustrates a cross-sectional view of the image sensor forming the multi-layer conductive layer, according to some embodiments of the present disclosure;

FIGS. 27, 28, 29, and 30 illustrate cross-sectional views of the image sensor patterning the multi-layer conductive layer, according to some embodiments of the present disclosure;

FIG. 31 illustrate a fragmentary cross-sectional view of the image sensor, according to some embodiments of the present disclosure;

FIG. 32 illustrates a transmittance view of the image sensor, according to some embodiments of the present disclosure; and

FIG. 33 illustrates a light absorption view of the image sensor, according to some embodiments of the present disclosure.

### DETAILED DESCRIPTION OF THE INVENTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during the manufacturing process, as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer with a thickness of “about 5 nm” can encompass a dimension range from 4.25 nm to 5.75 nm where manufacturing tolerances associated with depositing the material layer are known to be +/−15% by one of ordinary skill in the art.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

Generally, in order to increase the absorption efficiency of the photosensitive layer, the cavity of the photosensitive layer need to be enlarged. This may enhance the image quality. However, the greater the thickness of the photosensitive layer, the higher the cost. That is, the quantum dot layer in the photosensitive layer is relatively expensive compared to the materials of other layers. The embodiment of the present disclosure provides a novel optical spacer layer that enhances the cavity of the photosensitive layer, while maintaining the cost of the image sensor. In addition, combining the photosensitive layer and the optical spacer layer may apply to various photodiode (PD) products, such as smart phones, automotive components, and machine vision. Moreover, the embodiment of the present disclosure further provides a novel multi-layer conductive layer to replace the original top electrode and the anti-reflective coating layer. The multi-layer conductive layer also enhances the cavity of the photosensitive layer while maintaining the cost of the image sensor.

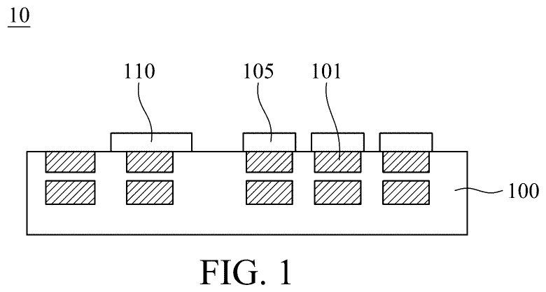

In the embodiments of the present disclosure, FIGS. 1 to 19 illustrate embodiments using two optical spacer layers to sandwich the photosensitive layer. FIG. 1 illustrates a cross-sectional view of the image sensor 10, according to some embodiments of the present disclosure. In some embodiments, a substrate 100 is provide. In some embodiments, a plurality of traces 101 may be buried in the substrate 100. In some embodiments, the substrate 100 may include a bottom electrode 105 and a top electrode 110 disposed on the top surface of the substrate 100. The bottom electrode 105 is spaced apart from the top electrode 110. More specifically, the bottom electrode 105 and the top electrode 110 may be in contact with the traces 101, and the traces 101 may be further connected to other components (not shown in FIG. 1 for the sake of simplicity). In some embodiments, materials of the bottom electrode 105 and the top electrode 110 include Cu, W, Ag, Au, Al, or a combination thereof. In some embodiments, the bottom electrode 105 and the top electrode 110 may be a single-layer structure or a multi-layer structure, such as including a Cu layer and a W layer.

Still refer to FIG. 1. In some embodiments, the substrate 100 may be an elemental semiconductor substrate, such as a silicon substrate, or a germanium substrate; a compound semiconductor substrate, such as silicon carbide (SiC), gallium arsenide (GaAs), indium arsenide (InAs), or indium phosphide (InP) substrate; or an alloy semiconductor substrate, such as SiGe, SiGeC, GaAsP, or GaInP. In other embodiments, the substrate 100 may be a semiconductor-on-insulator (SOI) substrate. The semiconductor-on-insulator substrate may include a base plate, a buried oxide layer disposed on the base plate, and a semiconductor layer disposed on the buried oxide layer.

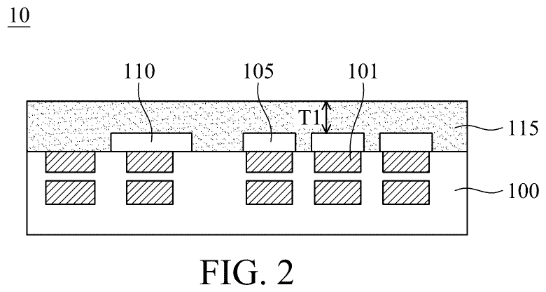

FIG. 2 illustrates a cross-sectional view of the image sensor 10 forming the bottom optical spacer layer 115, according to some embodiments of the present disclosure. In some embodiments, a bottom optical spacer layer 115 is formed on the substrate 100. The bottom optical spacer layer 115 has a first thickness T1 over the bottom electrode 105. The bottom optical spacer layer 115 covers the bottom electrode 105 and the top electrode 110. In some embodiments, the bottom optical spacer layer 115 is used to enhance the cavity of the photosensitive layer 120. That is, the bottom optical spacer layer 115 increases the absorption efficiency of the photosensitive layer 120. In some embodiments, the bottom optical spacer layer 115 may be formed by physical vapor deposition (PVD). In some embodiments, the material of the bottom optical spacer layer 115 includes transparent conductive oxides, high-conductivity polymers, carbon nanotubes, silver nanowires, and graphene. In some embodiments, the light transmittance of the bottom optical spacer layer 115 is greater than 90%, and the conductivity of the bottom optical spacer layer 115 is greater than 1000 S/cm.

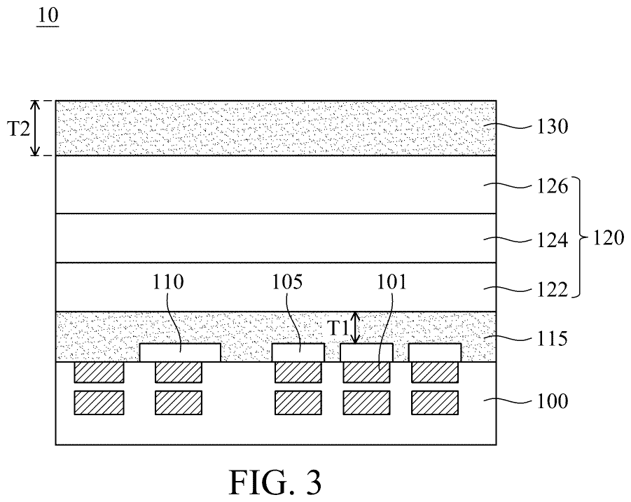

FIG. 3 illustrates a cross-sectional view of the image sensor 10 sequentially forming the photosensitive layer 120 and the top optical spacer layer 130, according to some embodiments of the present disclosure. In some embodiments, a photosensitive layer 120 is formed on the bottom optical spacer layer 115. More specifically, the photosensitive layer 120 includes an electric transmission layer 122, a quantum dot layer 124 on the electric transmission layer 122, and a hole transmission layer 126 on the quantum dot layer 124. That is, the electric transmission layer 122, the quantum dot layer 124, and the hole transmission layer 126 are sequentially formed on the bottom optical spacer layer 115. The quantum dot layer 124 may absorb the light and generate electron-hole pairs, where the electrons may move toward the electric transmission layer 122 and the holes may move toward the hole transmission layer 126, thereby generating an electronic signal. In some embodiments, the ratio of the quantum dot layer 124, the hole transmission layer 126, and the electric transmission layer 122 is 15:2:1. In some embodiments, the quantum dot layer 124, the hole transmission layer 126, and the electric transmission layer 122 may be formed by spin-on coating. In some embodiments, the material of the quantum dot layer 124 includes PbS. In some embodiments, the material of the electric transmission layer 122 includes ZnO and Al-doped ZnO. In some embodiments, the material of the hole transmission layer 126 includes NiO and MoO₃.

Still refer to FIG. 3. In some embodiments, a top optical spacer layer 130 is formed on the photosensitive layer 120. The top optical spacer layer 130 has a second thickness T2. In some embodiments, the top optical spacer layer 130 is used to enhance the cavity of the photosensitive layer 120. That is, the top optical spacer layer 130 increases the absorption efficiency of the photosensitive layer 120. In the embodiments of the present disclosure, the photosensitive layer 120 is sandwiched by the bottom optical spacer layer 115 and the top optical spacer layer 130 to enhance the cavity of the photosensitive layer 120, and the absorption efficiency of the photosensitive layer 120 may be further increased. In some embodiments, the second thickness T2 is greater than the first thickness T1. In some embodiments, the ratio of the second thickness T2 to the first thickness T1 is 8:3. In some embodiments, the top optical spacer layer 130 may be formed by physical vapor deposition (PVD). In some embodiments, the material of the top optical spacer layer 130 includes transparent conductive oxides, high-conductivity polymers, carbon nanotubes, silver nanowires, and graphene. In some embodiments, the light transmittance of the top optical spacer layer 130 is greater than 90%, and the conductivity of the top optical spacer layer 130 is greater than 1000 S/cm.

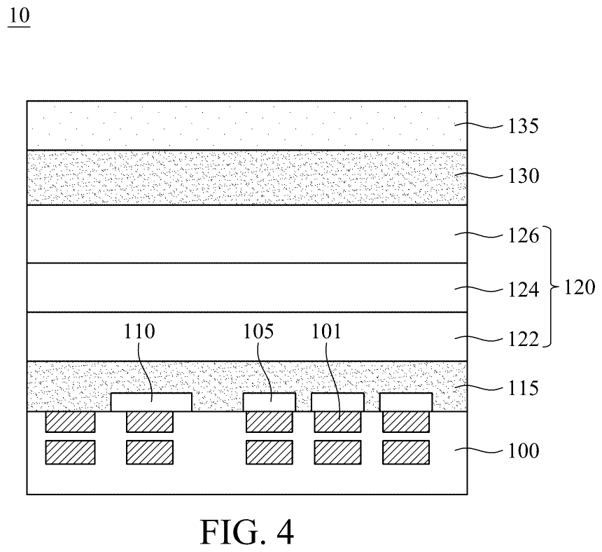

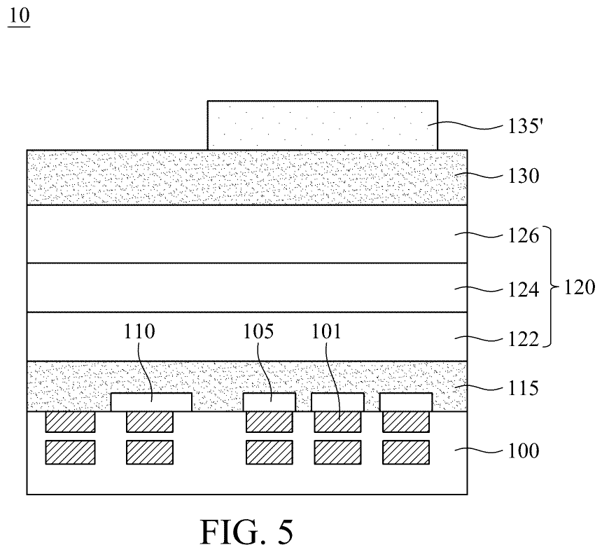

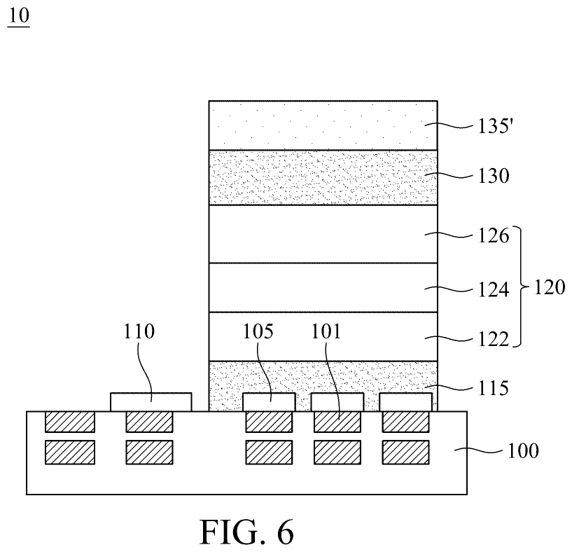

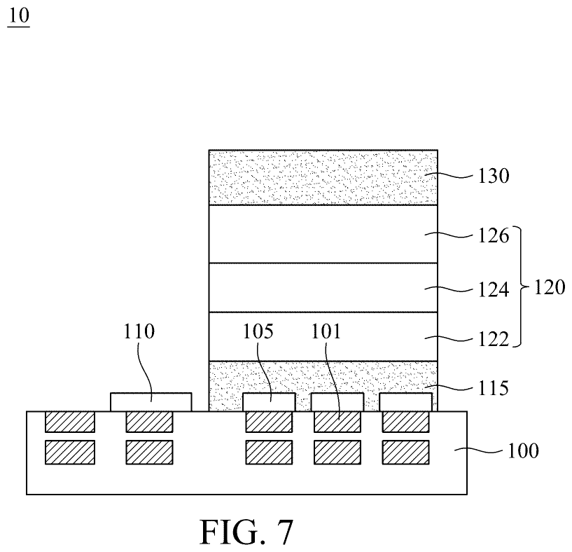

FIGS. 4, 5, 6, and 7 illustrate cross-sectional views of the image sensor 10 patterning the top optical spacer layer 130, the photosensitive layer 120, and the bottom optical spacer layer 115, according to some embodiments of the present disclosure. In some embodiments, as shown in FIG. 4, a photo resist layer 135 is formed on the top optical spacer layer 130. In some embodiments, as shown in FIG. 5, the photo resist layer 135 is patterned to form a first mask 135′, the first mask 135′ may define the dimension of the top optical spacer layer 130, the photosensitive layer 120, and the bottom optical spacer layer 115. In some embodiments, as shown in FIG. 6, using the first mask 135′ to pattern the top optical spacer layer 130, the photosensitive layer 120, and the bottom optical spacer layer 115 and expose the top electrode 110. In some embodiments, as shown in FIG. 7, the first mask 135′ is removed and expose the top surface of the top optical spacer layer 130. In some embodiments, the photo resist layer 135 may be formed by spin-on coating. In some embodiments, the top optical spacer layer 130, the photosensitive layer 120, and the bottom optical spacer layer 115 may be patterned by wet etching process. In some embodiments, the first mask 135′ may be removed by ashing process.

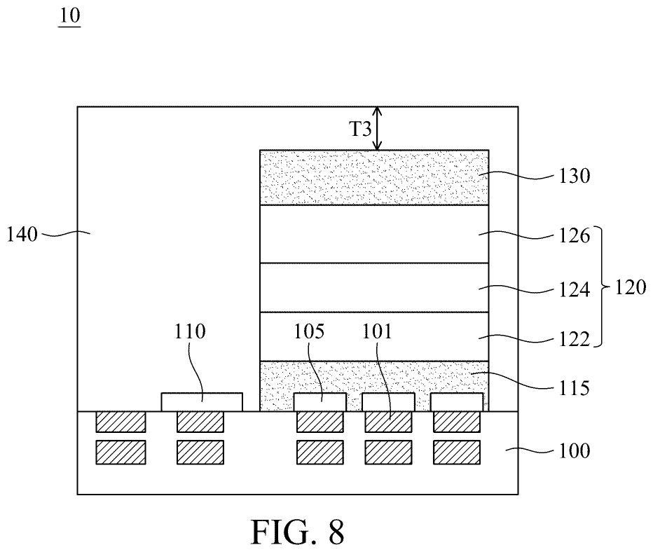

FIG. 8 illustrates a cross-sectional view of the image sensor 10 forming the conductive layer 140, according to some embodiments of the present disclosure. In some embodiments, a conductive layer 140 is formed on the substrate 100 to cover the top electrode 110 and the top optical spacer layer 130. The conductive layer 140 may connect the top optical spacer layer 130 to the top electrode 110. In some embodiments, the thickness T3 of the conductive layer 140 over the top optical spacer layer 130 is less than 50 nm. In some embodiments, the conductive layer 140 may be formed by physical vapor deposition (PVD).

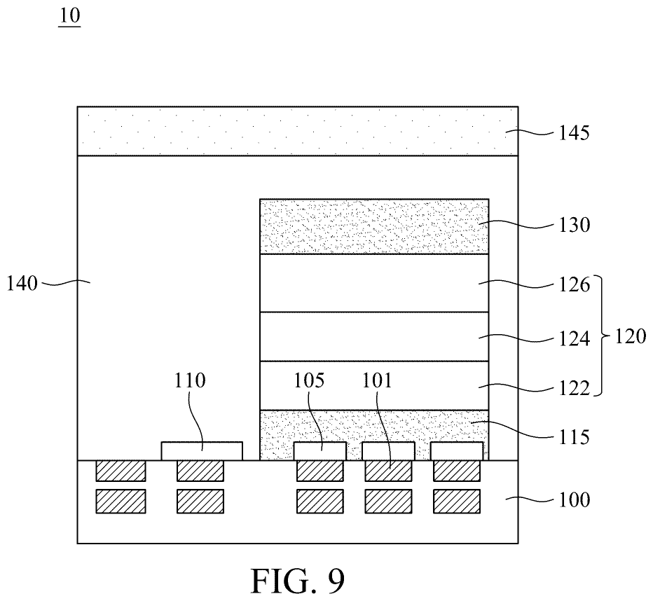

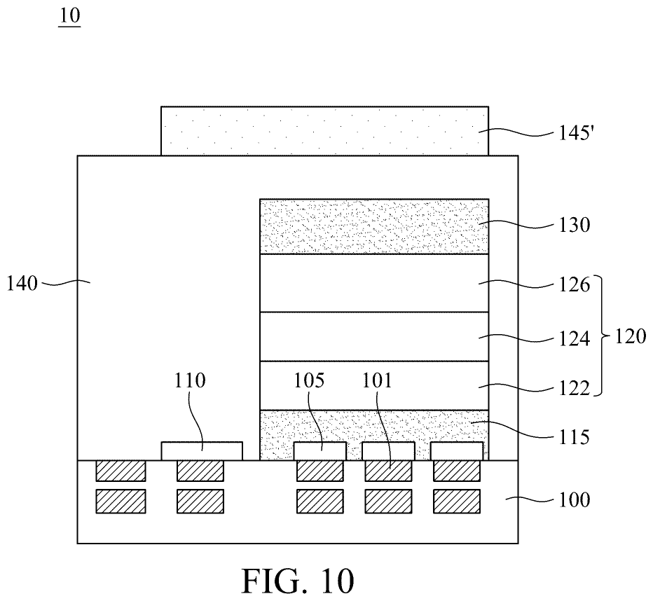

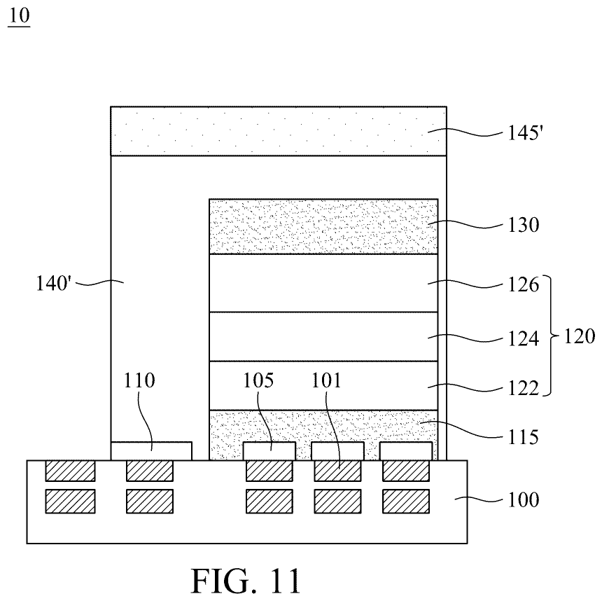

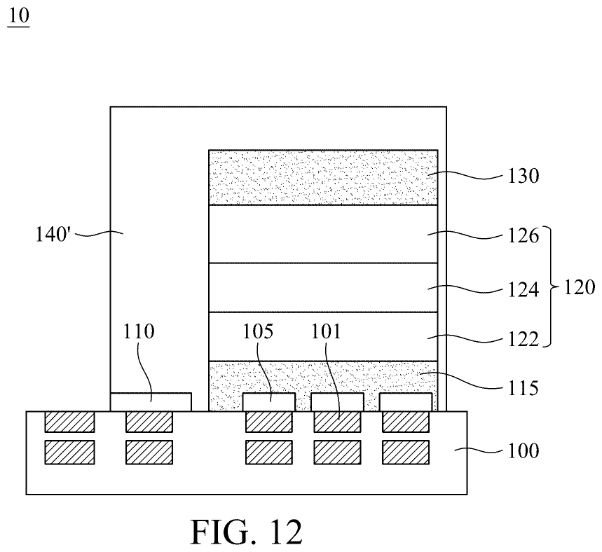

FIGS. 9, 10, 11, and 12 illustrate cross-sectional views of the image sensor 10 patterning the conductive layer 140, according to some embodiments of the present disclosure. In some embodiments, as shown in FIG. 9, a photo resist layer 145 is formed on the conductive layer 140. In some embodiments, as shown in FIG. 10, the photo resist layer 145 is patterned to form a second mask 145′, the second mask 145′ may define the dimension of the conductive layer 140′. In some embodiments, as shown in FIG. 11, using the second mask 145′ to pattern the conductive layer 140 to form the conductive layer 140′, and the top electrode 110 is covered by the conductive layer 140′. In some embodiments, as shown in FIG. 12, the second mask 145′ is removed and expose the top surface of the conductive layer 140′. In some embodiments, the photo resist layer 145 may be formed by spin-on coating. In some embodiments, the conductive layer 140 may be patterned by wet etching process. In some embodiments, the second mask 145′ may be removed by ashing process.

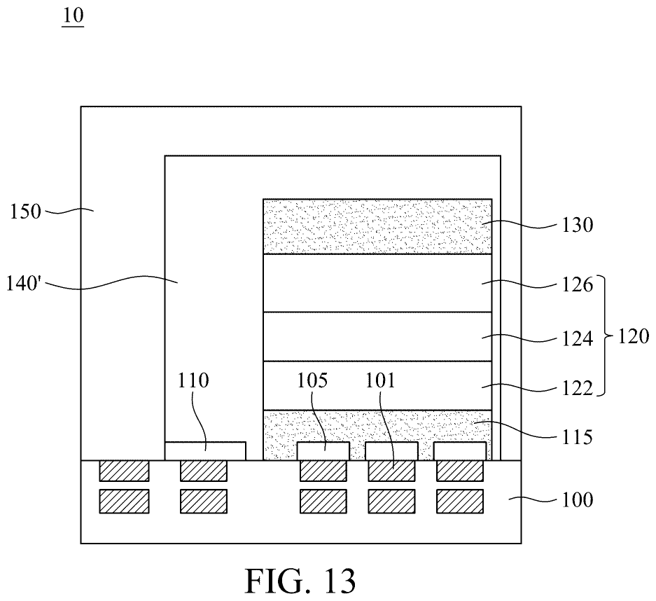

FIG. 13 illustrates a cross-sectional view of the image sensor 10 forming the anti-reflective coating layer 150, according to some embodiments of the present disclosure. In some embodiments, an anti-reflective coating layer 150 is formed on the substrate 100 to cover the conductive layer 140′. The anti-reflective coating layer 150 may further enhance the cavity of the photosensitive layer 120, avoiding the light to escape from the cavity. In some embodiments, the refractive index of the anti-reflective coating layer 150 is greater than 1.7. In some embodiments, the material of the anti-reflective coating layer 150 may include MoO₃. In some embodiments, the anti-reflective coating layer 150 may be formed by physical vapor deposition (PVD).

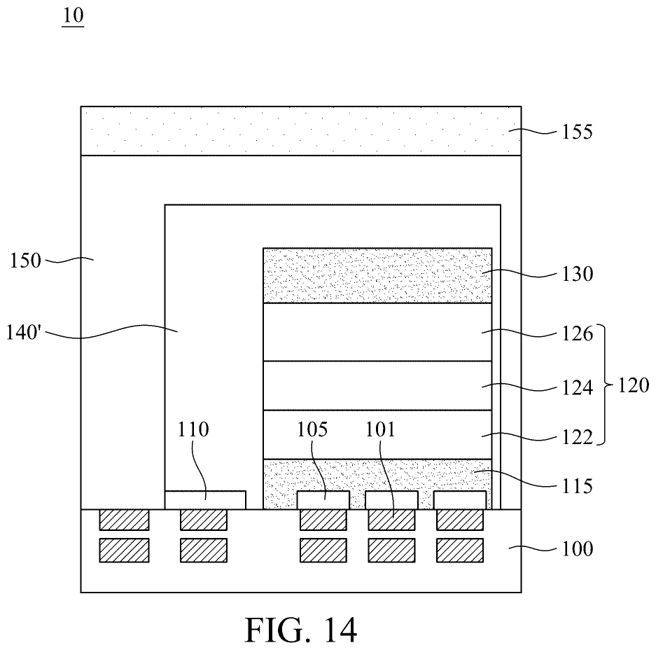

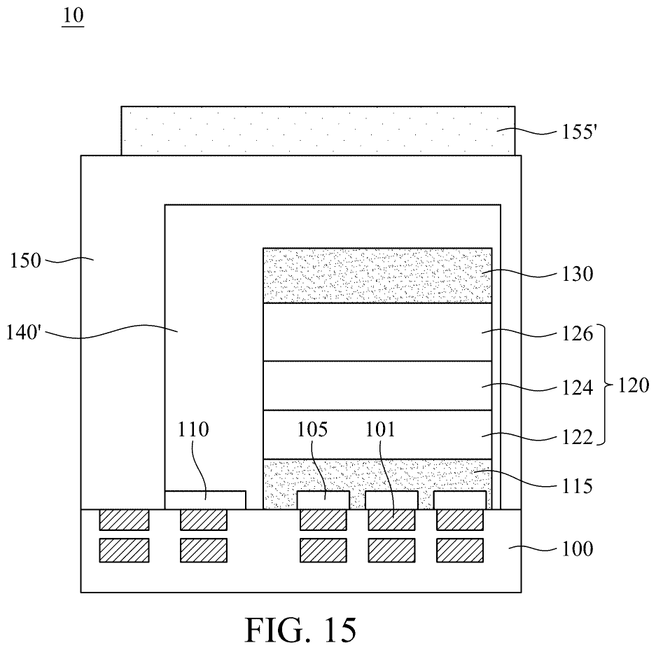

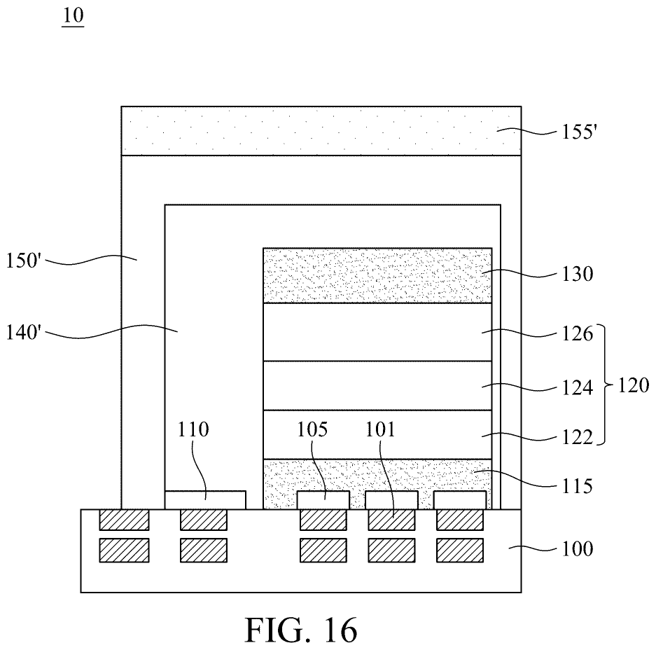

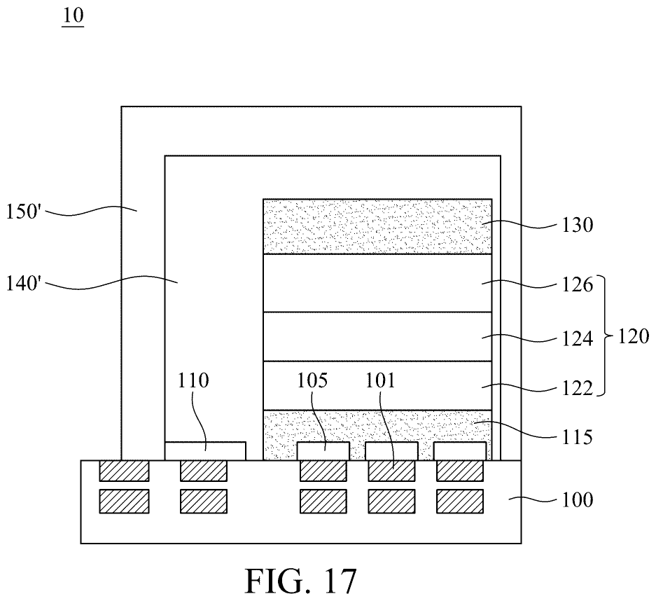

FIGS. 14, 15, 16, and 17 illustrate cross-sectional views of the image sensor 10 patterning the anti-reflective coating layer 150, according to some embodiments of the present disclosure. In some embodiments, as shown in FIG. 14, a photo resist layer 155 is formed on the anti-reflective coating layer 150. In some embodiments, as shown in FIG. 15, the photo resist layer 155 is patterned to form a third mask 155′, the third mask 155′ may define the dimension of the anti-reflective coating layer 150′. In some embodiments, as shown in FIG. 16, using the third mask 155′ to pattern the anti-reflective coating layer 150 to form the anti-reflective coating layer 150′, and the conductive layer 140′ is covered by the anti-reflective coating layer 150′. In some embodiments, as shown in FIG. 17, the third mask 155′ is removed and expose the top surface of the anti-reflective coating layer 150′. In some embodiments, the top optical spacer layer 130, the conductive layer 140′ (on the top optical spacer layer 130), and the anti-reflective coating layer 150′ (on the conductive layer 140′) may be collectively referred to as a multi-layer conductive layer. The multi-layer conductive layer electrically connects the top electrode 110 and the photosensitive layer 120, and the multi-layer conductive layer includes the top optical spacer layer 130 in direct contact with a top surface of the photosensitive layer 120. In some embodiments, the photo resist layer 155 may be formed by spin-on coating. In some embodiments, the anti-reflective coating layer 150 may be patterned by wet etching process. In some embodiments, the third mask 155′ may be removed by ashing process.

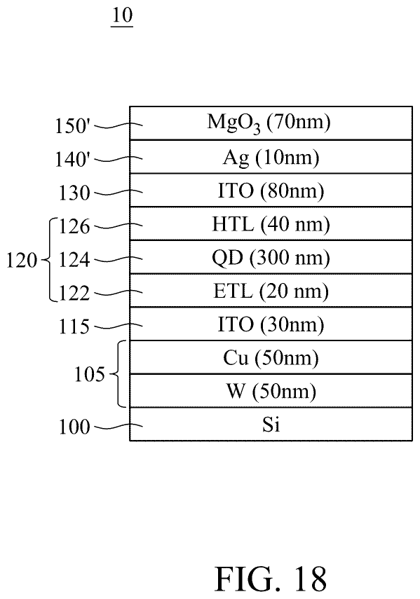

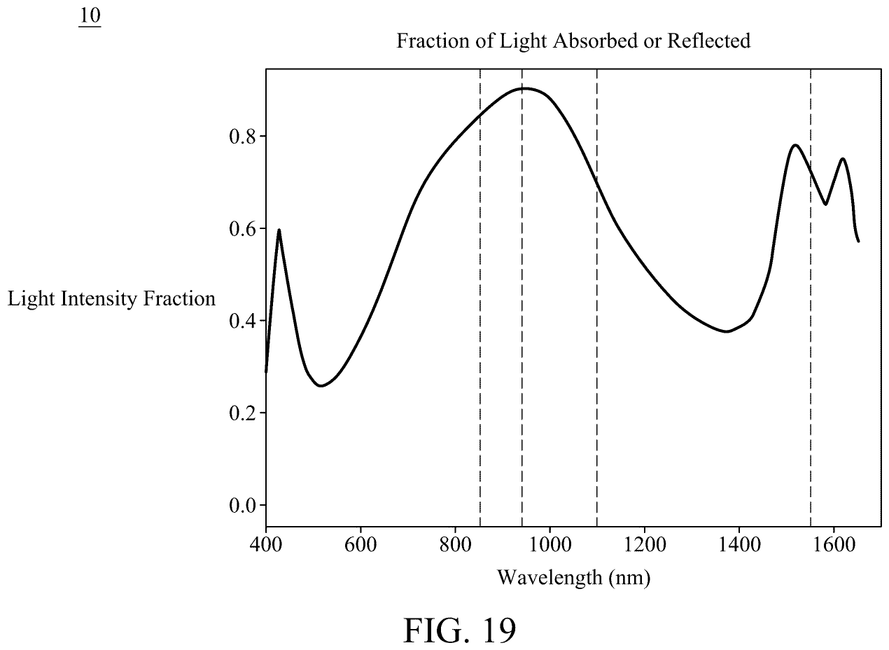

FIG. 18 illustrates a fragmentary cross-sectional view of the image sensor 10, according to some embodiments of the present disclosure. FIG. 19 illustrates a light absorption view of the image sensor 10, according to some embodiments of the present disclosure. As shown in FIG. 18, an example of the present disclosure is shown. In the embodiments, a preferred combination of thicknesses is provided. By using the preferred combination of thicknesses and the configuration of the bottom optical spacer layer 115 and the top optical spacer layer 130, as shown in FIG. 19, the absorption rate of the photosensitive layer 120 at a wavelength of 1550 nm is about 80%. In the embodiments, the bottom electrode 105 includes two different layers, a W layer of 50 nm and a Cu layer of 50 nm over the W layer. In some embodiments, the thickness of the bottom optical spacer layer 115 ranges from about 10 nm to about 50 nm, and the thickness of the top optical spacer layer 130 ranges from about 60 nm to about 100 nm. In the embodiments, the thickness of the bottom optical spacer layer 115 is 30 nm, and the thickness of the top optical spacer layer 130 is 80 nm. In some embodiments, the difference between the thickness of the bottom optical spacer layer 115 and the thickness of the top optical spacer layer 130 may be about 50 nm. In the embodiments, the thickness of the quantum dot layer 124 is 300 nm, the thickness of the hole transmission layer 126 is 40 nm, and the thickness of the electric transmission layer 122 is 20 nm. In the embodiments, the conductive layer 140′ includes an Ag layer of 10 nm, and the anti-reflective coating layer 150′ includes a MoO₃ layer of 70 nm. More specifically, the conductive layer 140′ shown in FIG. 18 may be considered as the top electrode of the image sensor 10, since the conductive layer 140′ is connected to the top electrode 110 (shown in FIG. 17). However, any suitable combination of thicknesses and configuration may also be used.

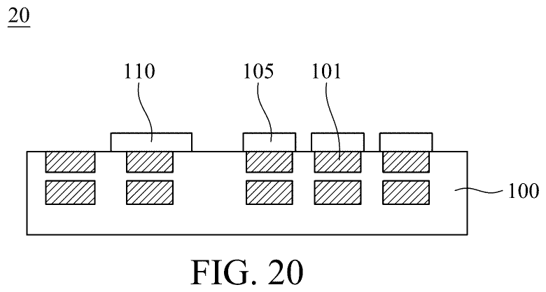

In the embodiments of the present disclosure, FIGS. 20 to 33 illustrate embodiments using a multi-layer conductive layer as the optical spacer layer and the top electrode. FIG. 20 illustrates a cross-sectional view of the image sensor 20, according to some embodiments of the present disclosure. In some embodiments, a substrate 100 is provide. In some embodiments, a plurality of traces 101 may be buried in the substrate 100. In some embodiments, the substrate 100 may include a bottom electrode 105 and a top electrode 110 disposed on the top surface of the substrate 100. More specifically, the bottom electrode 105 and the top electrode 110 may be in contact with the traces 101, and the traces 101 may be further connected to other components (not shown in FIG. 20 for the sake of simplicity). In some embodiments, materials of the bottom electrode 105 and the top electrode 110 include Cu, W, Ag, Au, Al, or a combination thereof. In some embodiments, the bottom electrode 105 and the top electrode 110 may be a single-layer structure or a multi-layer structure, such as including a Cu layer and a W layer.

Still refer to FIG. 20. In some embodiments, the substrate 100 may be an elemental semiconductor substrate, such as a silicon substrate, or a germanium substrate; a compound semiconductor substrate, such as silicon carbide (SiC), gallium arsenide (GaAs), indium arsenide (InAs), or indium phosphide (InP) substrate; or an alloy semiconductor substrate, such as SiGe, SiGeC, GaAsP, or GaInP. In other embodiments, the substrate 100 may be a semiconductor-on-insulator (SOI) substrate. The semiconductor-on-insulator substrate may include a base plate, a buried oxide layer disposed on the base plate, and a semiconductor layer disposed on the buried oxide layer.

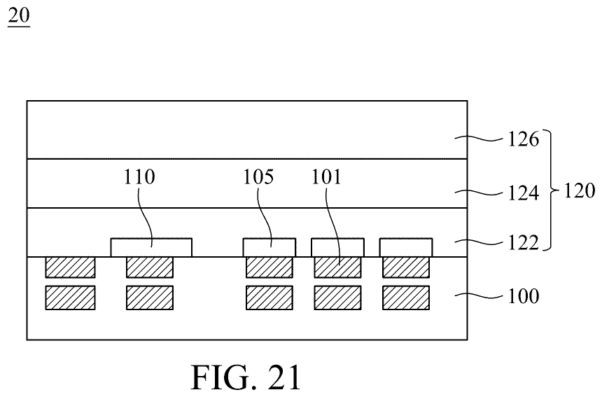

FIG. 21 illustrates a cross-sectional view of the image sensor 20 forming the photosensitive layer 120, according to some embodiments of the present disclosure. In some embodiments, a photosensitive layer 120 is formed on the substrate 100 and covers the bottom electrode 105 and the top electrode 110. More specifically, the photosensitive layer 120 includes an electric transmission layer 122, a quantum dot layer 124 on the electric transmission layer 122, and a hole transmission layer 126 on the quantum dot layer 124. That is, the electric transmission layer 122, the quantum dot layer 124, and the hole transmission layer 126 are sequentially formed on the substrate 100. The quantum dot layer 124 may absorb the light and generate electron-hole pairs, where the electrons may move toward the electric transmission layer 122 and the holes may move toward the hole transmission layer 126, thereby generating an electronic signal. In some embodiments, the ratio of the quantum dot layer 124, the hole transmission layer 126, and the electric transmission layer 122 is 15:2:1. In some embodiments, the quantum dot layer 124, the hole transmission layer 126, and the electric transmission layer 122 may be formed by spin-on coating. In some embodiments, the material of the quantum dot layer 124 includes PbS. In some embodiments, the material of the electric transmission layer 122 includes ZnO and Al-doped ZnO. In some embodiments, the material of the hole transmission layer 126 includes NiO and MOO₃.

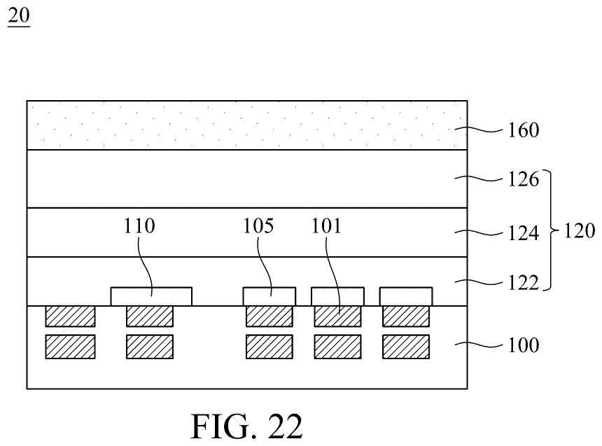

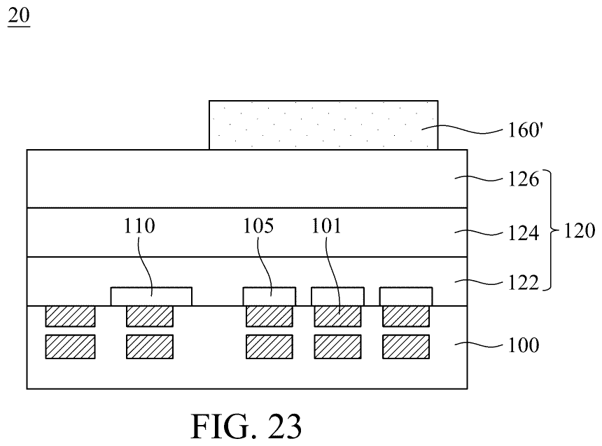

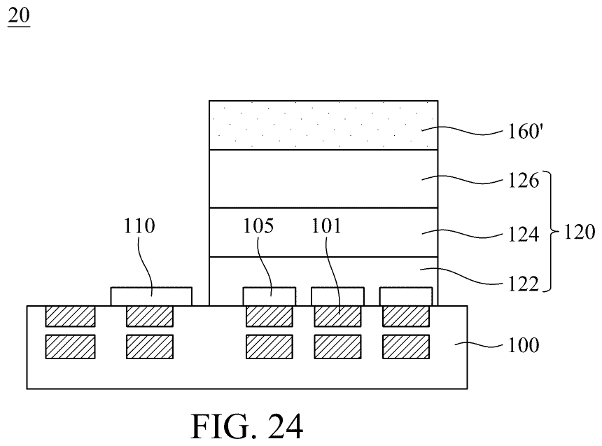

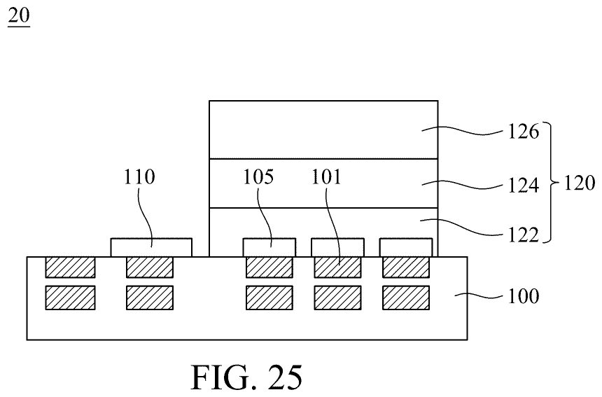

FIGS. 22, 23, 24, and 25 illustrate cross-sectional views of the image sensor 20 patterning the photosensitive layer 120, according to some embodiments of the present disclosure. In some embodiments, as shown in FIG. 22, a photo resist layer 160 is formed on the photosensitive layer 120. In some embodiments, as shown in FIG. 23, the photo resist layer 160 is patterned to form a fourth mask 160′, the fourth mask 160′ may define the dimension of the photosensitive layer 120. In some embodiments, as shown in FIG. 24, using the fourth mask 160′ to pattern the photosensitive layer 120 and expose the top electrode 110. In some embodiments, as shown in FIG. 25, the fourth mask 160′ is removed and expose the top surface of the photosensitive layer 120. In some embodiments, the photo resist layer 160 may be formed by spin-on coating. In some embodiments, the photosensitive layer 120 may be patterned by wet etching process. In some embodiments, the fourth mask 160′ may be removed by ashing process.

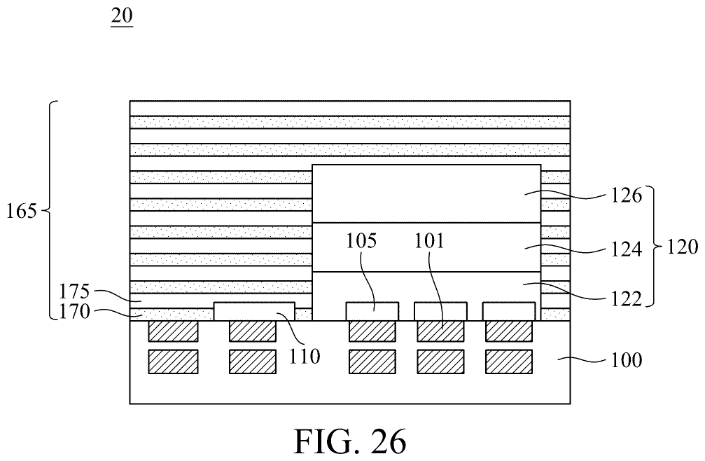

FIG. 26 illustrates a cross-sectional view of the image sensor 20 forming the multi-layer conductive layer 165, according to some embodiments of the present disclosure. In some embodiments, a multi-layer conductive layer 165 is formed on the substrate 100 to cover the top electrode 110 and the photosensitive layer 120. The multi-layer conductive layer 165 may connect the photosensitive layer 120 to the top electrode 110. In some embodiments, the multi-layer conductive layer 165 may be used as a color filter, an arc film (e.g., the anti-reflective coating layer 150′), a top electrode (e.g., the conductive layer 140′), and an optical spacer layer (e.g., the top optical spacer layer 130). In some embodiments, the multi-layer conductive layer 165 has a reflective surface. In some embodiments, the multi-layer conductive layer 165 includes a plurality of first conductive layers 170 interleaved with a plurality of second conductive layers 175. In some embodiments, the bottommost layer of the multi-layer conductive layer 165 is the first conductive layers 170, and the topmost portion of the multi-layer conductive layer 165 is the second conductive layers 175, and the bottommost layer of the multi-layer conductive layer 165 may function as the top optical spacer layer. In some embodiments, the material of the first conductive layers 170 includes indium zinc oxides (IZO). In some embodiments, the material of the second conductive layers 175 includes GeH. In some embodiments, the multi-layer conductive layer 165 (e.g., the first conductive layers 170 and the second conductive layers 175) may be formed by physical vapor deposition (PVD).

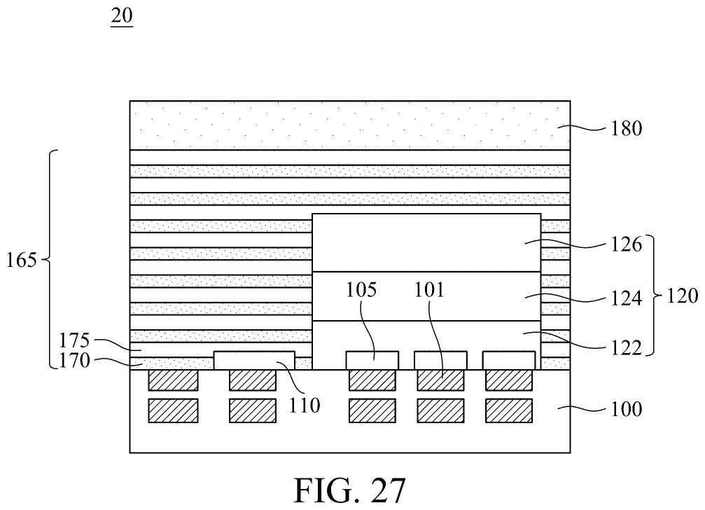

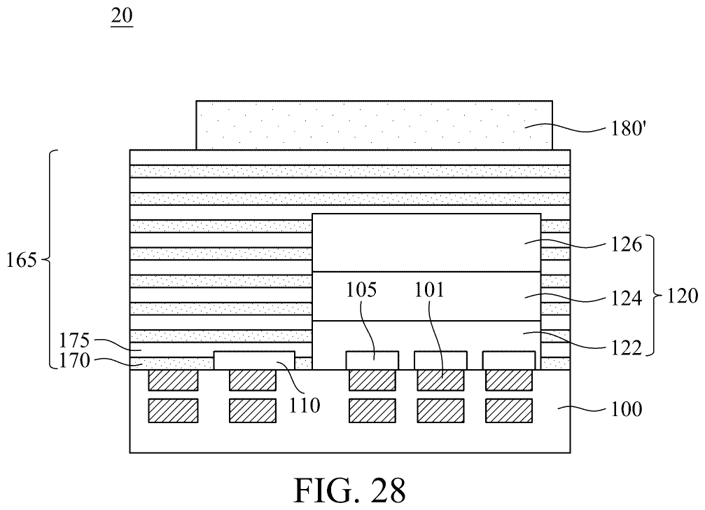

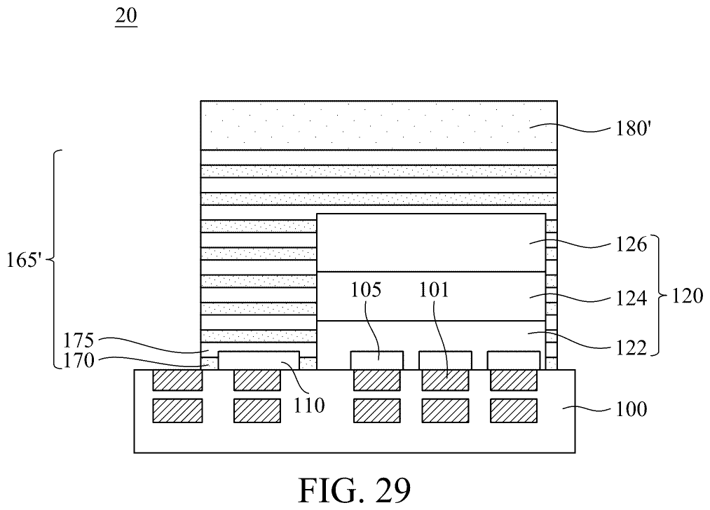

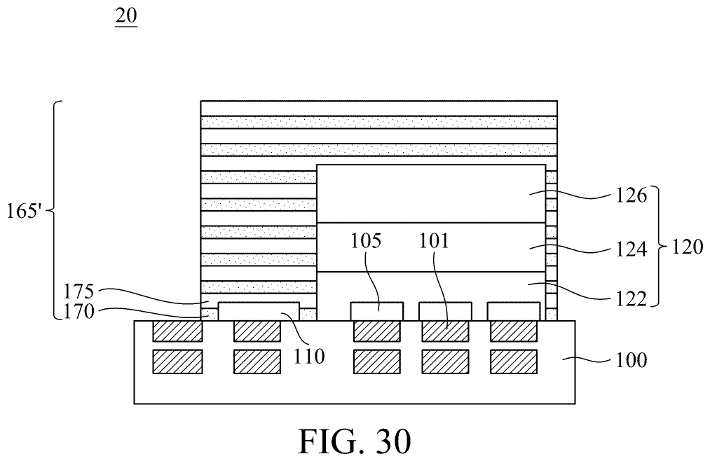

FIGS. 27, 28, 29, and 30 illustrate cross-sectional views of the image sensor 20 patterning the multi-layer conductive layer 165, according to some embodiments of the present disclosure. In some embodiments, as shown in FIG. 27, a photo resist layer 180 is formed on the multi-layer conductive layer 165. In some embodiments, as shown in FIG. 28, the photo resist layer 180 is patterned to form a fifth mask 180′, the fifth mask 180′ may define the dimension of the multi-layer conductive layer 165. In some embodiments, as shown in FIG. 29, using the fifth mask 180′ to pattern the multi-layer conductive layer 165 to form the multi-layer conductive layer 165′, and the photosensitive layer 120 and the top electrode 110 are covered by the multi-layer conductive layer 165′. That is, the multi-layer conductive layer 165′ surrounds the photosensitive layer 120. In some embodiments, as shown in FIG. 30, the fifth mask 180′ is removed and expose the top surface of the multi-layer conductive layer 165′. In some embodiments, the photo resist layer 180 may be formed by spin-on coating. In some embodiments, the multi-layer conductive layer 165 may be patterned by wet etching process. In some embodiments, the fifth mask 180′ may be removed by ashing process.

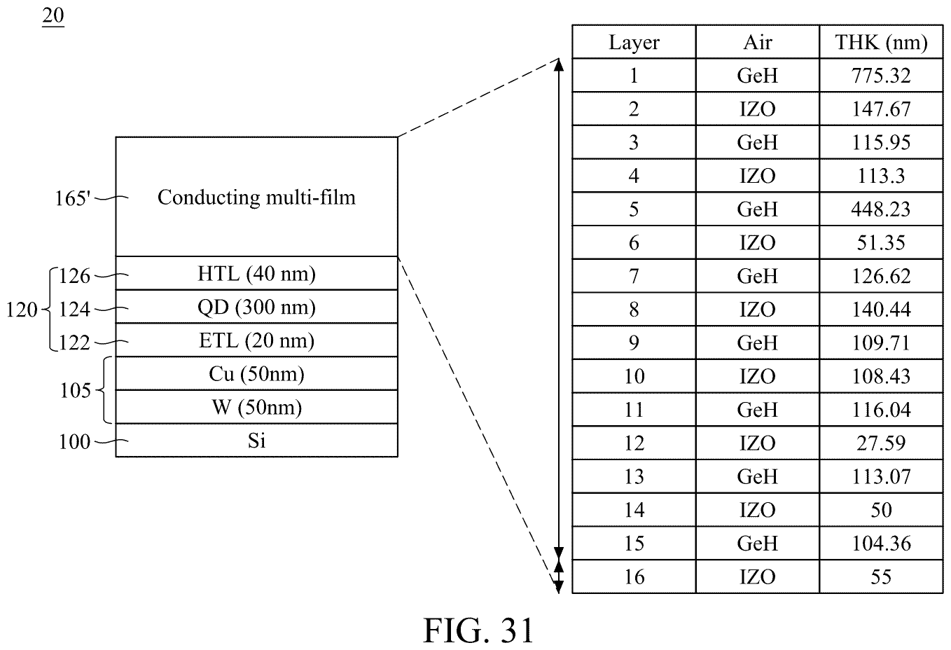

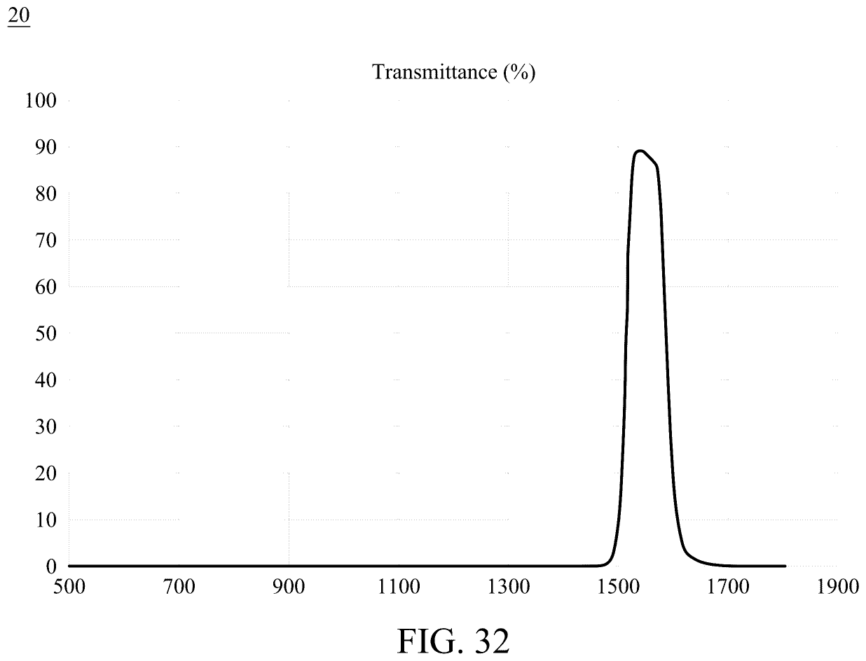

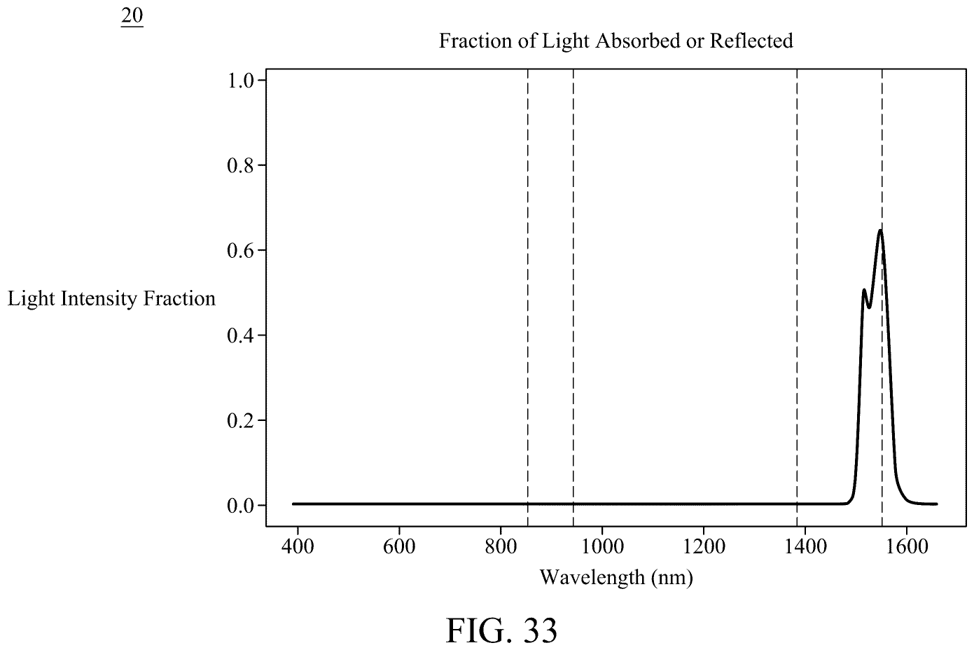

FIG. 31 illustrates a fragmentary cross-sectional view of the image sensor 20, according to some embodiments of the present disclosure. FIG. 32 illustrates a transmittance view of the image sensor 20, according to some embodiments of the present disclosure. FIG. 33 illustrates a light absorption view of the image sensor 20, according to some embodiments of the present disclosure. As shown in FIG. 31, another example of the present disclosure is shown. In the embodiments, a preferred combination of thicknesses and a preferred number of the multi-layer conductive layer 165′ are provided. In the embodiments, the multi-layer conductive layer 165′ shown in FIG. 31 may be considered as the top electrode of the image sensor 20, since the multi-layer conductive layer 165′ is connected to the top electrode 110 (shown in FIG. 30). In the embodiments, the bottommost layer of the multi-layer conductive layer 165′ is the first conductive layers 170, and the bottommost layer of the multi-layer conductive layer 165′ may be considered as the optical spacer layer. In the embodiments, the multi-layer conductive layer 165′ includes 16 layers. In the embodiments, as shown in FIG. 32, when the multi-layer conductive layer 165′ includes 16 layers, the transmittance of the multi-layer conductive layer 165 at a wavelength of 1550 nm is about 90%. By using the preferred combination of thicknesses and the preferred number of the multi-layer conductive layer 165′, as shown in FIG. 33, the absorption of the photosensitive layer 120 at a wavelength of 1550 nm is about 64%.

Still refer to FIG. 31. In the embodiments, the bottom electrode 105 includes two different layers, a W layer of 50 nm and a Cu layer of 50 nm over the W layer. In the embodiments, the thickness of the quantum dot layer 124 is 300 nm, the thickness of the hole transmission layer 126 is 40 nm, and the thickness of the electric transmission layer 122 is 20 nm. In the embodiments, thicknesses of the first conductive layers 170 from bottom to top may be 55 nm, 50 nm, 27.59 nm, 108.43 nm, 140.44 nm, 51.35 nm, 113.3 nm, and 147.67 nm. In the embodiments, thicknesses of the second conductive layers 175 from bottom to top may be 104.36 nm, 113.07 nm, 116.04 nm, 109.71 nm, 126.62 nm, 448.23 nm, 115.95 nm, and 775.32 nm. However, any suitable combination of thicknesses and any suitable number of the multi-layer conductive layer may also be used.

In summary, the embodiment of the present disclosure provides a novel optical spacer layer that enhances the cavity of the photosensitive layer, while maintaining the cost of the image sensor. In addition, combining the photosensitive layer and the optical spacer layer may apply to various photodiode (PD) products, such as smart phones, automotive components, and machine vision. Moreover, the embodiment of the present disclosure further provides a novel multi-layer conductive layer to replace the original top electrode and the anti-reflective coating layer. The multi-layer conductive layer also enhances the cavity of the photosensitive layer while maintaining the cost of the image sensor. Thus, the various embodiments described herein offer several advantages over the existing art. It will be understood that not all advantages have been necessarily discussed herein, no particular advantage is required for all embodiments, and other embodiments may offer different advantages.

The embodiments of the present disclosure provide a method of manufacturing an image sensor. The method includes providing a substrate and forming a bottom electrode and a top electrode on a top surface of the substrate. The bottom electrode is spaced apart from the top electrode. The method includes forming a photosensitive layer over the substrate to cover the bottom electrode and the top electrode. The method includes patterning the photosensitive layer to expose the top electrode. The method includes forming a multi-layer conductive layer over the substrate. The multi-layer conductive layer electrically connects the top electrode and the photosensitive layer, and the multi-layer conductive layer includes a top optical spacer layer in direct contact with a top surface of the photosensitive layer.

In some embodiments, before forming the photosensitive layer, the method further includes forming a bottom optical spacer layer on the substrate, the bottom optical spacer layer has a first thickness over the bottom electrode, and the photosensitive layer is formed on the bottom optical spacer layer. After forming the photosensitive layer, the method further includes forming the top optical spacer layer with a second thickness on the photosensitive layer. Patterning the photosensitive layer further includes patterning the bottom optical spacer layer, the photosensitive layer, and the top optical spacer layer at a same time to expose the top electrode, and the second thickness is greater than the first thickness. In some embodiments, the multi-layer conductive layer includes the top optical spacer layer, a conductive layer on the top optical spacer layer, and an anti-reflective coating layer on the conductive layer, a thickness of the conductive layer over the top optical spacer layer is less than 50 nm, and a refractive index of the anti-reflective coating layer is greater than 1.7. In some embodiments, the ratio of the second thickness to the first thickness is 8:3. In some embodiments, materials of the bottom optical spacer layer and the top optical spacer layer include transparent conductive oxides, high-conductivity polymers, carbon nanotubes, silver nanowires, and graphene. In some embodiments, a light transmittance of the bottom optical spacer layer and the top optical spacer layer is greater than 90%, and a conductivity of the bottom optical spacer layer and the top optical spacer layer is greater than 1000 S/cm. In some embodiments, the material of the bottom electrode includes Cu, W, Ag, Au, Al, or a combination thereof. In some embodiments, the photosensitive layer includes an electric transmission layer, a quantum dot layer on the electric transmission layer, and a hole transmission layer on the quantum dot layer. In some embodiments, the ratio of the quantum dot layer, the hole transmission layer, and the electric transmission layer is 15:2:1. In some embodiments, the multi-layer conductive layer includes a plurality of first conductive layers interleaved with a plurality of second conductive layers, a bottommost layer of the multi-layer conductive layer is one of the first conductive layers, and a topmost layer of the multi-layer conductive layer is one of the second conductive layers, and the bottommost layer of the multi-layer conductive layer is the top optical spacer layer. In some embodiments, the multi-layer conductive layer includes 16 layers, and a transmittance of the multi-layer conductive layer at a wavelength of 1550 nm is about 90%. In some embodiments, a material of the first conductive layers includes indium zinc oxides, and a material of the second conductive layers includes GeH.

The embodiments of the present disclosure provide an image sensor. The image sensor includes a substrate. The image sensor includes a bottom electrode and a top electrode disposed on the substrate, the bottom electrode is spaced apart from the top electrode. The image sensor includes a photosensitive layer disposed over the bottom electrode. The image sensor includes a multi-layer conductive layer disposed over the substrate, the multi-layer conductive layer electrically connects the photosensitive layer and the top electrode, the multi-layer conductive layer includes a top optical spacer layer in direct contact with a top surface of the photosensitive layer.

In some embodiments, the image sensor further includes a bottom optical spacer layer disposed on the bottom electrode and below the photosensitive layer, the bottom optical spacer layer has a first thickness on the bottom electrode, the top optical spacer layer has a second thickness, and the second thickness is greater than the first thickness. In some embodiments, the multi-layer conductive layer includes the top optical spacer layer, a conductive layer disposed on the top optical spacer layer, and an anti-reflective coating layer disposed on the conductive layer. In some embodiments, a ratio of the second thickness to the first thickness is 8:3. In some embodiments, an absorption rate of the photosensitive layer at a wavelength of 1550 nm is about 80%. In some embodiments, the photosensitive layer includes an electric transmission layer, a quantum dot layer on the electric transmission layer, and a hole transmission layer on the quantum dot layer, and wherein the ratio of the quantum dot layer, the hole transmission layer, and the electric transmission layer is 15:2:1. In some embodiments, the material of the quantum dot layer includes PbS, the material of the electric transmission layer includes ZnO and Al-doped ZnO, and the material of the hole transmission layer includes NiO and MoO₃. In some embodiments, the multi-layer conductive layer includes a plurality of first conductive layers interleaved with a plurality of second conductive layers, and a bottommost layer of the multi-layer conductive layer is one of the first conductive layers, and a topmost layer of the multi-layer conductive layer is one of the second conductive layers, and the bottommost layer of the multi-layer conductive layer is the top optical spacer layer. In some embodiments, the absorption of the photosensitive layer at a wavelength of 1550 nm is about 64%.

The scope of the present disclosure is not limited to the technical solutions consisting of specific combinations of the technical features described above, but should also cover other technical solutions consisting of any combinations of the technical features described above or their equivalent features, all of which are within the scope of the protection of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the prior art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A method of manufacturing an image sensor, comprising:
providing a substrate;
forming a bottom electrode and a top electrode on a top surface of the substrate, wherein the bottom electrode is spaced apart from the top electrode;
forming a photosensitive layer over the substrate to cover the bottom electrode and the top electrode;
patterning the photosensitive layer to expose the top electrode; and
forming a multi-layer conductive layer over the substrate, wherein the multi-layer conductive layer electrically connects the top electrode and the photosensitive layer, wherein the multi-layer conductive layer comprises a top optical spacer layer in direct contact with a top surface of the photosensitive layer.

2. The method as claimed in claim 1, wherein:
before forming the photosensitive layer, the method further comprises forming a bottom optical spacer layer on the substrate, the bottom optical spacer layer has a first thickness over the bottom electrode, and the photosensitive layer is formed on the bottom optical spacer layer,
after forming the photosensitive layer, the method further comprises forming the top optical spacer layer with a second thickness on the photosensitive layer,
patterning the photosensitive layer further comprises patterning the bottom optical spacer layer, the photosensitive layer, and the top optical spacer layer at a same time to expose the top electrode, and
the second thickness is greater than the first thickness.

3. The method as claimed in claim 2, wherein:
the multi-layer conductive layer comprises the top optical spacer layer, a conductive layer on the top optical spacer layer, and an anti-reflective coating layer on the conductive layer,
a thickness of the conductive layer over the top optical spacer layer is less than 50 nm, and
a refractive index of the anti-reflective coating layer is greater than 1.7.

4. The method as claimed in claim 2, wherein a ratio of the second thickness to the first thickness is 8:3.

5. The method as claimed in claim 2, wherein materials of the bottom optical spacer layer and the top optical spacer layer comprise transparent conductive oxides, high-conductivity polymers, carbon nanotubes, silver nanowires, and graphene.

6. The method as claimed in claim 2, wherein a light transmittance of the bottom optical spacer layer and the top optical spacer layer is greater than 90%, and a conductivity of the bottom optical spacer layer and the top optical spacer layer is greater than 1000 S/cm.

7. The method as claimed in claim 1, wherein a material of the bottom electrode comprises Cu, W, Ag, Au, Al, or a combination thereof.

8. The method as claimed in claim 1, wherein the photosensitive layer comprises an electric transmission layer, a quantum dot layer on the electric transmission layer, and a hole transmission layer on the quantum dot layer, and wherein a ratio of the quantum dot layer, the hole transmission layer, and the electric transmission layer is 15:2:1.

9. The method as claimed in claim 1, wherein the multi-layer conductive layer comprises a plurality of first conductive layers interleaved with a plurality of second conductive layers, wherein a bottommost layer of the multi-layer conductive layer is one of the first conductive layers, and a topmost layer of the multi-layer conductive layer is one of the second conductive layers, and the bottommost layer of the multi-layer conductive layer is the top optical spacer layer.

10. The method as claimed in claim 9, wherein the multi-layer conductive layer comprises 16 layers, and wherein a transmittance of the multi-layer conductive layer at a wavelength of 1550 nm is about 90%.

11. The method as claimed in claim 9, wherein a material of the first conductive layers comprises indium zinc oxides, and wherein a material of the second conductive layers comprises GeH.

12. An image sensor, comprising:
a substrate;
a bottom electrode and a top electrode disposed on the substrate, wherein the bottom electrode is spaced apart from the top electrode;
a photosensitive layer disposed over the bottom electrode; and
a multi-layer conductive layer disposed over the substrate, wherein the multi-layer conductive layer electrically connects the photosensitive layer and the top electrode, wherein the multi-layer conductive layer comprises a top optical spacer layer in direct contact with a top surface of the photosensitive layer.

13. The image sensor as claimed in claim 12, further comprising:
a bottom optical spacer layer disposed on the bottom electrode and below the photosensitive layer, wherein the bottom optical spacer layer has a first thickness on the bottom electrode,
wherein the top optical spacer layer has a second thickness, and the second thickness is greater than the first thickness.

14. The image sensor as claimed in claim 13, wherein the multi-layer conductive layer comprises the top optical spacer layer, a conductive layer disposed on the top optical spacer layer, and an anti-reflective coating layer disposed on the conductive layer.

15. The image sensor as claimed in claim 13, wherein a ratio of the second thickness to the first thickness is 8:3.

16. The image sensor as claimed in claim 15, wherein an absorption rate of the photosensitive layer at a wavelength of 1550 nm is about 80%.

17. The image sensor as claimed in claim 12, wherein the photosensitive layer comprises an electric transmission layer, a quantum dot layer on the electric transmission layer, and a hole transmission layer on the quantum dot layer, and wherein a ratio of the quantum dot layer, the hole transmission layer, and the electric transmission layer is 15:2:1.

18. The image sensor as claimed in claim 17, wherein a material of the quantum dot layer comprises PbS, wherein a material of the electric transmission layer comprises ZnO and Al-doped ZnO, and wherein a material of the hole transmission layer comprises NiO and MOO₃.

19. The image sensor as claimed in claim 12, wherein the multi-layer conductive layer comprises a plurality of first conductive layers interleaved with a plurality of second conductive layers, and wherein a bottommost layer of the multi-layer conductive layer is one of the first conductive layers, and a topmost layer of the multi-layer conductive layer is one of the second conductive layers, and wherein the bottommost layer of the multi-layer conductive layer is the top optical spacer layer.

20. The image sensor as claimed in claim 19, wherein the multi-layer conductive layer comprises 16 layers, and wherein an absorption rate of the photosensitive layer at a wavelength of 1550 nm is about 64%.
